(19) United States
(12) Patent Application Publication
(10) Pub. No.: US 2021/0345518 A1
(43) Pub. Date: Nov. 4, 2021

(54) DEVICE AND HEAT RADIATION METHOD

(71) Applicant: Showa Denko Materials Co., Ltd., Tokyo (JP)

(72) Inventors: Maki TAKAHASHI, Chiyoda-ku, Tokyo (JP); Takashi ANDOU, Chiyoda-ku, Tokyo (JP); Yoshitaka TAKEZAWA, Chiyoda-ku, Tokyo (JP); Takanobu KOBAYASHI, Chiyoda-ku, Tokyo (JP); Naoki MARUYAMA, Chiyoda-ku, Tokyo (JP)

(73) Assignee: Showa Denko Materials Co., Ltd., Tokyo (JP)

(21) Appl. No.: 17/281,993

(22) PCT Filed: Sep. 11, 2019
(86) PCT No.: PCT/JP2019/035749

§ 371 Date: Apr. 1, 2021

(30) Foreign Application Priority Data
Oct. 4, 2018 (JP) PCT/JP2018/037247

(51) Int. Cl. H05K 7/20; H05K 1/02

(52) U.S. Cl. CPC H05K 7/2039; H01L 23/3737; H05K 1/0203

(57) ABSTRACT

A device which includes a heat generator, a resinous housing covering the heat generator, and a heat radiation material disposed on at least some of the surfaces of the heat generator, wherein the heat radiation material includes metal particles and a resin and has a region where the metal particles arranged along the surface direction are present at a relatively high density.

### TECHNICAL FIELD

The present invention relates to a device and a heat radiation method.

### BACKGROUND ART

In recent years, with the miniaturization and multi-functionalization of devices that generate heat such as electronic equipment, there has been a trend that the amount of heat generated per unit area has increased. Therefore, there is an increasing need to radiate the generated heat to the outside of the device.

For example, Patent Literature 1 discloses that a housing is surface-treated for the purpose of transferring heat generated by electronic components to a metallic housing covering the electronic components and radiating the heat from the inner and outer surfaces of the housing to the atmosphere.

### REFERENCE LIST

### Patent Literature

Patent Literature 1: Japanese Patent Laid-Open No. 2004-304200

### SUMMARY

### Technical Problem

In the related art, metallic housings have been used as housings for devices that generate heat, but resin housings are increasingly being employed to reduce weight. However, when a resin having a lower thermal conductivity than a metal is used for the housing, heat is likely to accumulate inside the housing, and problems such as device failure, shortened life, reduced operational stability, and reduced reliability occur.

In view of the above circumstances, an aspect of the present invention is to provide a device and a heat radiation method capable of efficiently radiating heat from inside a resinous housing.

### Solution to Problem

Means for solving the above problems include the following embodiments.

<1> A device including a heat generator; a resinous housing covering the heat generator; and a heat radiation material disposed on at least some of a surface of the heat generator, wherein the heat radiation material contains metal particles and a resin and has a region where the metal particles arranged in a surface direction are present at a relatively high density.

<2> The device according to claim 1, wherein the heat generator is an electronic component, and wherein the device further includes a circuit board on which the electronic component is mounted; and the heat radiation material disposed on at least some of a surface of the circuit board.

<3> The device according to <1> or <2>, wherein a thickness of the heat radiation material is in a range of 0.1 μm to 100 μm.

<4> The device according to any one of <1> to <3>, wherein a proportion of a thickness of the region in a total thickness of the heat radiation material is in a range of 0.02% to 99%.

<5> The device according to any one of <1> to <4>, wherein the region has an uneven structure derived from the metal particles on a surface thereof.

<6> The device according to any one of <1> to <5>, wherein the heat radiation material includes a region 1 and a region 2 satisfying the following (A) and (B).

(A) A total value of absorption of electromagnetic waves at a wavelength of 2 μm to 6 μm in a region 1>A total value of absorption of electromagnetic waves at a wavelength of 2 μm to 6 μm in a region 2

(B) a metal particle occupancy rate in the region 1>a metal particle occupancy rate in the region 2

<7> The device according to any one of <1> to <5>, wherein the heat radiation material includes a region 1, a region 2, and a region 3 satisfying the following (A) and (B).

(A) a total value of absorption of electromagnetic waves at a wavelength of 2 μm to 6 μm in the region 2>a total value of absorption of electromagnetic waves at a wavelength of 2 μm to 6 μm in the region 1 and the region 3

(B) a metal particle occupancy rate in the region 2>metal particle occupancy rates in the region 1 and the region 3

<8> The device according to any one of <1> to <7>, wherein a total value of absorption of electromagnetic waves at a wavelength of 2 μm to 6 μm in the heat radiation material is larger than a total value of absorption of electromagnetic waves at a wavelength of 2 μm to 6 μm in the resinous housing.

<9> A device including a heat generator; a resinous housing covering the heat generator; and a heat radiation material disposed on at least some of a surface of the heat generator, wherein the heat radiation material has a base material layer that contains a resin and has an uneven structure on at least one surface thereof and a metal layer that is disposed on the surface side of the base material layer having the uneven structure and has a shape corresponding to the uneven structure.

<10> A device including a heat generator; a resinous housing covering the heat generator; and a heat radiation material disposed on at least some of a surface of the heat generator, wherein the heat radiation material has a resin layer and a metal pattern layer including a region A in which a metal is present and a region B in which a metal is not present.

<11> A heat radiation method including a step of disposing a heat radiation material on at least some of a surface of a heat generator covered with a resinous housing, wherein the heat radiation material contains metal particles and a resin and has a region where the metal particles arranged in a surface direction are present at a relatively high density.

### Advantageous Effects of Invention

According to the aspect of the present invention, there is provided a device and a heat radiation method capable of efficiently radiating heat from inside the resinous housing.

### BRIEF DESCRIPTION OF THE DRAWINGS

FIG. 1 is a schematic cross-sectional view of electronic equipment manufactured in Example 1.

FIG. 2 is a schematic cross-sectional view of electronic equipment manufactured in Example 3.

FIG. 3 is a schematic cross-sectional view of electronic equipment manufactured in Example 4.

FIG. 4 is a schematic cross-sectional view of electronic equipment manufactured in Example 5.

FIG. 5 is a schematic cross-sectional view of a specific example of a heat radiation material.

FIG. 6 is a schematic cross-sectional view of a specific example of a heat radiation material.

FIG. 7 is a schematic cross-sectional view of a specific example of a heat radiation material.

FIG. 8 is a schematic cross-sectional view of a specific example of a heat radiation material.

FIG. 9 is a schematic cross-sectional view of a specific example of a heat radiation material.

FIG. 10 is a schematic cross-sectional view of a specific example of a heat radiation material.

FIG. 11 is a schematic cross-sectional view of a specific example of a heat radiation material.

FIG. 12 is a schematic cross-sectional view of a specific example of a heat radiation material.

FIG. 13 is a schematic cross-sectional view of a specific example of a heat radiation material.

FIG. 14 is a schematic cross-sectional view of a specific example of a heat radiation material.

FIG. 15 is an absorption wavelength spectrum of a heat radiation material manufactured in Example 1.

FIG. 16 is an absorption wavelength spectrum of a resinous housing used in Example 1.

### DESCRIPTION OF THE EMBODIMENTS

Hereinafter, embodiments for carrying out the present invention will be described in detail. However, the present invention is not limited to the following embodiments. In the following embodiments, the constituent elements (also including individual operations and the like) thereof are not essential unless otherwise specified. The same applies to the numerical values and their ranges, which do not limit the present invention.

In the present disclosure, the term “step” includes not only a step independent of another step but also a step if the purpose of the step is achieved even when the step cannot be clearly distinguished from another step.

In the present disclosure, a numerical range indicated using “to” includes the numerical values before and after “to” as a minimum value and a maximum value, respectively.

In numerical ranges stated in a stepwise manner in the present disclosure, the upper limit value or the lower limit value stated in one numerical range may be replaced with the upper limit value or the lower limit value of another numerical range stated in a stepwise manner. Further, in the numerical range stated in the present disclosure, the upper limit value or the lower limit value of the numerical range may be replaced with the value shown in the examples.

In the present disclosure, each component may contain a plurality of substances corresponding thereto. When a plurality of substances corresponding to each component is present in the composition, the concentration or content of each component means the total concentration or content of the plurality of substances present in the composition unless otherwise specified.

In the present disclosure, a plurality of types of particles corresponding to each component may be included. When a plurality of types of particles corresponding to each component is present in the composition, the particle size of each component means a value for a mixture of the plurality of types of particles present in the composition unless otherwise specified.

In the present disclosure, the term “layer” includes, when a region where the layer is present is observed, not only a case in which the layer is formed in the entire region but also a case in which the layer is formed in only some of the region.

When the embodiments are described in the present disclosure with reference to the drawings, the configuration of the embodiments is not limited to the configuration shown in the drawings. Further, the size of the members in each figure is conceptual, and the relative relationship between the sizes of the members is not limited to this.

Specific configurations, preferred aspects, and the like of each embodiment in the present disclosure can be applied to others in the embodiments. For example, heat radiation materials used in different embodiments can be used in combination with each other for the same device.

### Device (First Embodiment)

A device of the present disclosure is a device that includes a heat generator; a resinous housing covering the heat generator; and a heat radiation material disposed on at least some of a surface of the heat generator, wherein the heat radiation material contains metal particles and a resin and has a region where the metal particles arranged in a surface direction are present at a relatively high density.

In the above device, heat generated from the heat generator is unlikely to accumulate inside the resinous housing, and increase in temperature thereof can be suppressed. Therefore, problems such as device failure, shortened life, reduced operational stability, and reduced reliability are unlikely to occur. Further, a configuration of a cooling system (for example, air cooling or water cooling by fins or the like) provided in the device can be simplified or omitted.

At least some of the heat generator inside the resinous housing is provided with a heat radiation material on a surface thereof. As a result, temperature rise inside the resinous housing is suppressed and an excellent heat radiation effect is achieved. The reasons for this are not necessarily clear, but they are thought to be as follows.

The heat radiation material has a region (hereinafter referred to as a metal particle layer) where the metal particles arranged in a surface direction are present at a relatively high density.

In the present disclosure, the “surface direction” means a direction along a principal surface of the heat radiation material, and the “region where the metal particles are present at a relatively high density” means a region where the metal particles are present in high density as compared with other regions of the heat radiation material.

It is thought that the metal particle layer has a fine uneven structure due to a shape of the metal particles on a surface thereof, and thus, when heat is transferred from the heat generator to the metal particle layer, surface plasmon resonance occurs, and a wavelength range of electromagnetic waves that are emitted changes. As a result, it is thought that, for example, the emission of electromagnetic waves in the wavelength range which the resin contained in the resinous housing and the heat radiation material is unlikely to absorb relatively increases, heat accumulation by the resin is reduced, and heat radiation performance is improved.

The type of the heat generator included in the device is not particularly limited. Examples of the heat generator include integrated circuits, electronic components such as semiconductor elements, power sources such as engines, electric power sources such as lithium ion secondary batteries, light sources such as light emitting diodes, coils, magnets, cooling or heating devices, piping, and the like.

The type and use of the device are not particularly limited. For example, the device may be used for electronic equipment such as computers, audio equipment, image display devices, home appliances, automobiles, transportation means such as airplanes, air conditioning equipment, power generation equipment, machines, and the like.

The device may include a heat radiation material disposed on a surface of a member other than the heat generator, in addition to the heat radiation material disposed on at least some of a surface of the heat generator. For example, the device may include a heat radiation material disposed on a surface of a member (such as a circuit board on which electronic components are mounted) that supports a heat generator. Alternatively, the device may include a heat radiation material disposed on a surface of the resinous housing.

Hereinafter, as an embodiment of the device of the present disclosure, an example of a basic configuration of electronic equipment incorporating electronic components will be described with reference to the drawings.

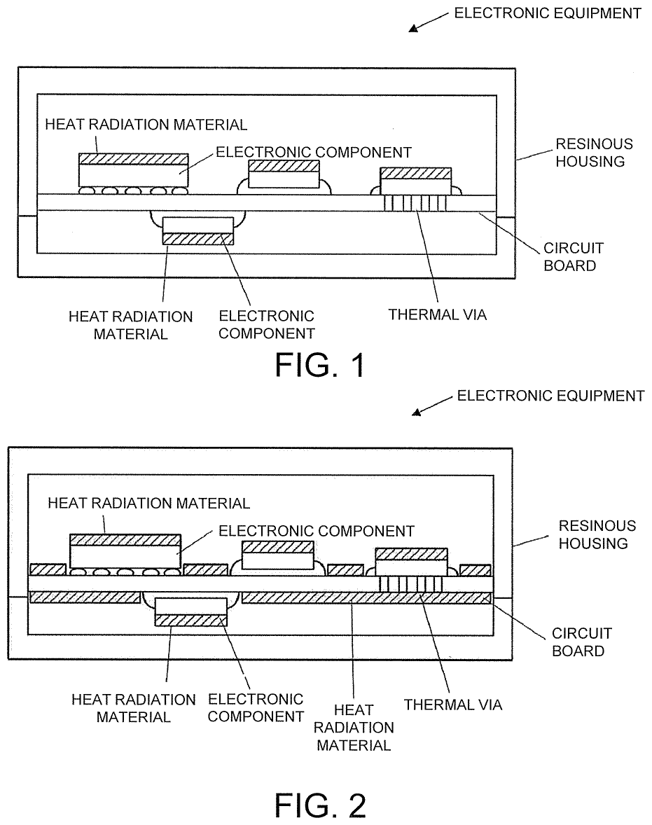

FIG. 1 is a cross-sectional view schematically showing a configuration of electronic equipment manufactured in Example 1. The electronic equipment is configured to include a circuit board on which electronic components are mounted using solder or the like, a resinous housing in which the circuit board is housed, and a heat radiation material disposed on a surface of each of the electronic components. The circuit board may be provided with a thermal via (a through hole) as needed.

FIG. 2 is a cross-sectional view schematically showing a configuration of electronic equipment manufactured in Example 3. In the configuration shown in FIG. 2, in addition to the configuration shown in FIG. 1, a heat radiation material is also disposed on a surface of the circuit board.

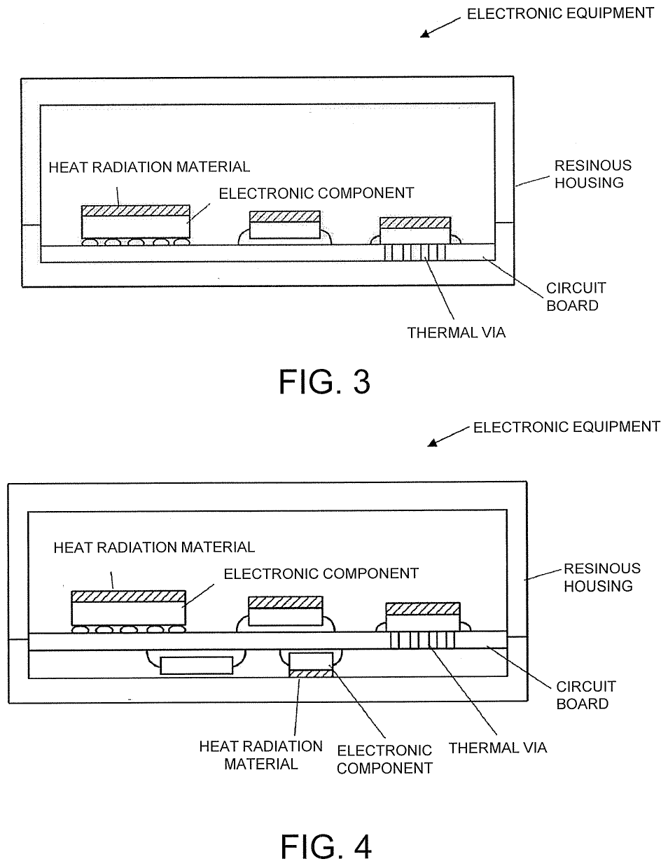

FIG. 3 is a cross-sectional view schematically showing a configuration of electronic equipment manufactured in Example 4. In the configuration shown in FIG. 3, the circuit board is disposed to be in contact with a surface (a bottom surface) of the resinous housing.

FIG. 4 is a cross-sectional view schematically showing a configuration of electronic equipment manufactured in Example 5. In the configuration shown in FIG. 4, some of the electronic components are disposed to be in contact with a surface (a bottom surface) of the resinous housing (directly or via the heat radiation material).

<Resinous Housing>

In the present disclosure, the “resinous housing” means a member whose main material (for example, 60% by volume or more of the entire housing) is a resin and which has a shape capable of covering the heat generator.

The entire resinous housing may be constituted by one member or may be constituted by two or more members. The resinous housing is manufactured by, for example, injection molding, press molding, cutting, or the like. From the viewpoint of protecting the heat generator from the external environment, it is preferable that the resinous housing forms a closed (isolated from the outside) space inside.

The type of the resin contained in the resinous housing is not particularly limited and can be selected from known thermosetting resins, thermoplastic resins, ultraviolet curable resins, and the like. Specifically, examples of the resin include a phenol resin, an alkyd resin, an amino-alkyd resin, a urea resin, a silicone resin, a melamine urea resin, an epoxy resin, a polyurethane resin, an unsaturated polyester resin, a vinyl acetate resin, an acrylic resin, a rubber chloride resin, a vinyl chloride resin, a fluororesin, and the like. Among these, an acrylic resin, an unsaturated polyester resin, an epoxy resin, and the like are preferable from the viewpoint of heat resistance, availability, and the like. The resin contained in the resinous housing may be only of one type or may be of two or more types.

The resinous housing may contain a material other than a resin as needed. For example, it may contain inorganic particles such as ceramics, additives, and the like. Moreover, the resinous housing may have a metal member in a part.

A method of disposing the heat radiation material on a surface of the heat generator is not particularly limited.

For example, when a composition such as varnish is used as a material of the heat radiation material, a method of forming a layer of the composition on the surface of the heat generator is exemplified. As a preferable example of the method of forming the layer of the composition, an application method such as brush application, spray coating, dip coating, and the like is exemplified, but electrostatic coating, curtain coating, electrodeposition coating, and the like may be used depending on an object to be applied. When the layer of the composition is dried, a method such as natural drying or baking is preferably used.

When a sheet-shaped heat radiation material is used, a method of attaching the heat radiation material to the heat generator directly or using an adhesive is exemplified. The method of performing attachment is not particularly limited, and a known method such as roll attachment can be employed.

<Heat Radiation Material>

The heat radiation material contains metal particles and a resin and has a region (a metal particle layer) where the metal particles arranged in a surface direction are present at a relatively high density.

Since the heat radiation material includes a metal particle layer, the surface plasmon resonance is caused by the incidence of electromagnetic waves. Therefore, it is possible to cause the surface plasmon resonance by a simple method as compared with, for example, a method of causing the surface plasmon resonance by processing a surface of a metal plate to form a fine uneven structure.

Further, since the heat radiation material contains a resin, this heat radiation material is more likely deformed according to a shape of a surface of an attachment target and it is possible to achieve superior adhesion to a metallic heat radiation material

A form of the metal particle layer is not particularly limited as long as it can cause the surface plasmon resonance. For example, a clear boundary may be formed or may not be formed between the metal particle layer and the other region. Further, the metal particle layer may be continuously present in the heat radiation material or may be present discontinuously (including a pattern).

The metal particles contained in the metal particle layer may be or may not be in contact with adjacent particles. Further, the metal particles contained in the metal particle layer may include or may not include particles overlapping each other in a thickness direction.

The thickness of the metal particle layer (if the thickness is not constant, the thickness of a portion where the thickness is a minimum) is not particularly limited. For example, it may be in the range of 0.1 μm to 100 μm. It is possible to adjust the thickness of the metal particle layer, for example, by adjusting the amount of metal particles contained in the metal particle layer, the size of the metal particles, and the like.

The proportion of the metal particle layer in the entire heat radiation material is not particularly limited. For example, the proportion of the thickness of the metal particle layer in the total thickness of the heat radiation material may be in the range of 0.02% to 99% or may be in the range of 1% to 50%.

The density of metal particles in the metal particle layer is not particularly limited as long as it can cause the surface plasmon resonance. For example, when the metal particle layer (or the heat radiation material) is observed from the front (a principal surface of the heat radiation material), the proportion of the metal particles in an observation surface is preferably 50% or more, more preferably 75% or more, and further preferably 90%, based on an area.

In the present disclosure, the “observation surface when observed from the front of the metal particle layer” means a surface observed in a direction (a thickness direction of the heat radiation material) perpendicular to an arrangement direction of the metal particles (a surface direction of the heat radiation material).

The above proportion can be calculated from, for example, an electron microscope image using image processing software.

In the present disclosure, the “metal particle” means a particle of which at least some of a surface is a metal, and the inside of the particle may be or may not be a metal. From the viewpoint of improving heat radiation performance due to heat conduction, the inside of the particle is preferably a metal.

A case in which at least some of the surface of the metal particle is a metal also includes a case in which a substance other than the metal such as a resin or a metal oxide is present around the metal particle if external electromagnetic waves can reach the surface of the metal particle.

Examples of the metal contained in the metal particle include copper, aluminum, nickel, iron, silver, gold, tin, titanium, chromium, palladium, and the like. The metal contained in the metal particle may be only of one type or may be of two or more types. Further, it may be a simple substance or may be an alloy.

The shape of the metal particles is not particularly limited as long as it can form a desired uneven structure on the surface of the metal particle layer. Specifically, examples of the shape of the metal particles include a spherical shape, a flake shape, a needle shape, a rectangular parallelepiped, a cube, a tetrahedron, a hexahedron, a polyhedron, a tubular shape, a hollow body, three-dimensional needle-shaped structure extending from a core in four different axial directions, and the like. Among these, a spherical shape or a shape close to a spherical shape is preferable.

The size of the metal particle is not particularly limited. For example, the volume average particle diameter of the metal particles is preferably in the range of 0.1 μm to 30 μm. When the volume average particle diameter of the metal particles is 30 μm or less, there is a trend that electromagnetic waves (particularly, infrared light having a relatively low wavelength) that contribute to the improvement of heat radiation performance are sufficiently emitted. When the volume average particle diameter of the metal particles is 0.1 μm or more, the cohesive force of the metal particles is suppressed, and there is a trend that the metal particles are easy to be evenly arranged.

The volume average particle diameter of the metal particles may be set in consideration of the type of material other than the metal particles used for the heat radiation material. For example, the smaller the volume average particle diameter of the metal particles, the smaller a period of the uneven structure formed on the surface of the metal particle layer, and the shorter a wavelength with which the surface plasmon resonance occurring in the metal particle layer is maximized. The absorption of the electromagnetic waves by the metal particle layer is maximum at a wavelength with which the surface plasmon resonance is maximum. Therefore, when a wavelength with which the surface plasmon resonance occurring in the metal particle layer is maximum becomes short, a wavelength with which the absorption of the electromagnetic waves by the metal particle layer is maximum becomes short, and there is a trend that the emission of the electromagnetic waves at the wavelength increases according to Kirchhoff's law. Therefore, by appropriately selecting the volume average particle diameter of the metal particles, it is possible to convert an emission wavelength of the metal particle layer into a wavelength range, the electromagnetic waves in which the resin contained in the heat radiation material is unlikely to absorb, and there is a trend that the heat radiation performance is further improved.

The volume average particle diameter of the metal particles contained in the metal particle layer may be 10 μm or less, may be 5 μm or less, or may be 3 μm or less. When the volume average particle diameter of the metal particles is in the above range, the wavelength range of the electromagnetic waves that are emitted can be converted into a low wavelength range (for example, 6 μm or less), the electromagnetic waves in which the resin is unlikely to absorb. As a result, heat accumulation by the resin can be reduced and heat radiation performance can be further improved.

In the present disclosure, the volume average particle diameter of the metal particles is a particle diameter (D50) at a cumulative value of 50% in a volume-based particle size distribution from a small diameter end obtained by a laser diffraction/scattering method.

From the viewpoint of effectively controlling the absorption or emission wavelength of electromagnetic waves by the metal particle layer, it is preferable that variation in the particle size of the metal particles contained in the metal particle layer is small. By suppressing the variation in the particle size of the metal particles, it becomes easy to form an uneven structure having periodicity on the surface of the metal particle layer, and there is a trend that the surface plasmon resonance easily occurs.

Regarding the variation in the particle size of the metal particles, for example, in the volume-based particle size distribution, a particle size (D10) at a cumulative value of 10% from a small diameter end is A (μm), and a particle size (D90) at a cumulative value of 90% from a small diameter end is B (μm), a value of A/B is preferably about 0.3 or more, more preferably about 0.4 or more, and further preferably about 0.6 or more.

The type of the resin contained in the heat radiation material is not particularly limited and can be selected from known thermosetting resins, thermoplastic resins, ultraviolet curable resins, and the like. Specifically, examples of the resin include a phenol resin, an alkyd resin, an amino-alkyd resin, a urea resin, a silicone resin, a melamine urea resin, an epoxy resin, a polyurethane resin, an unsaturated polyester resin, a vinyl acetate resin, an acrylic resin, a rubber chloride resin, a vinyl chloride resin, a fluororesin, and the like. Among these, an acrylic resin, an unsaturated polyester resin, an epoxy resin, and the like are preferable from the viewpoint of heat resistance, availability, and the like. The resin contained in the metal particle layer may be of only one type or may be of two or more types.

The heat radiation material may contain a material other than the resin and the metal particles. For example, it may contain ceramic particles, additives, and the like.

Since the heat radiation material contains ceramic particles, for example, the heat radiation effect of the heat radiation material can be further enhanced. Specifically, examples of the ceramic particles include particles of boron nitride, aluminum nitride, aluminum oxide, magnesium oxide, titanium oxide, zirconia, iron oxide, copper oxide, nickel oxide, cobalt oxide, lithium oxide, silicon dioxide, and the like. The ceramic particles contained in the metal particle layer may be of only one type or may be of two or more types. Further, the surface may be covered with a film formed of a resin, an oxide, and the like.

The size and shape of the ceramic particles are not particularly limited. For example, they may be the same as those described as the preferred aspect of the size and the shape of the metal particles described above.

Since the heat radiation material contains additives, a desired function can be imparted to the heat radiation material or the material for forming the heat radiation material. Specifically, examples of the additives include a dispersant, a film forming auxiliary, a plasticizer, a pigment, a silane coupling agent, a viscosity modifier, and the like.

The shape of the heat radiation material is not particularly limited and can be selected according to the use and the like. Examples of the shape of the heat radiation material include a sheet shape, a film shape, a plate shape, and the like. Alternatively, it may be in a state of a layer formed by applying a heat radiation material to the heat generator.

The thickness of the heat radiation material (if the thickness is not constant, the thickness of a portion where the thickness is a minimum) is not particularly limited. For example, the thickness of the heat radiation material is preferably in the range of 1 μm to 500 μm, and more preferably 10 μm to 200 μm. When the thickness of the heat radiation material is 500 μm or less, there is a trend that the heat radiation material is unlikely to become a heat insulation layer, and excellent heat radiation performance is maintained. When the thickness of the heat radiation material is 1 μm or more, there is a trend that the function of the heat radiation material is sufficiently obtained.

The wavelength range of the electromagnetic waves that are absorbed or emitted by the heat radiation material is not particularly limited, but from the viewpoint of thermal emission performance, it is preferable that the absorption or the emission is closer to 1.0 for each wavelength of 3 μm to 30 μm at room temperature (25° C.). Specifically, the absorption or the emission is preferably 0.8 or more, and more preferably 0.9 or more.

The absorption or the emission of the electromagnetic waves can be measured by an emissivity measuring device (for example, D and S AERD manufactured by Kyoto Electronics Manufacturing Co., Ltd.), a Fourier transform infrared spectrophotometer, or the like. According to Kirchhoff's law, it conceivable that the absorption and the emission of the electromagnetic waves are equal.

The wavelength range of the electromagnetic waves that are absorbed or emitted by the heat radiation material can be measured by a Fourier transform infrared spectrophotometer. Specifically, the transmittance and the reflectance of each wavelength can be measured and calculated by the following formula.

Absorption (emission)=1−transmittance−reflectance

A total value of absorption of electromagnetic waves at a wavelength of 2 μm to 6 μm in the heat radiation material is larger than a total value of absorption of electromagnetic waves at a wavelength of 2 μm to 6 μm in the resinous housing.

The electromagnetic waves at a wavelength of 2 μm to 6 μm are unlikely to be absorbed by the resin (are likely to be transmitted). Therefore, it can be said that a device provided with the heat radiation material satisfying the above conditions is more likely to emit infrared radiation in the wavelength range in which the infrared rays are transmitted through the resinous housing and has a superior heat radiation performance to a device not provided with the heat radiation material.

The metal particle layer preferably has an uneven structure derived from the metal particles on a surface thereof. It is thought that, when heat is transferred from the heat generator to the metal particle layer having an uneven structure derived from the metal particles on a surface thereof, surface plasmon resonance occurs, and a wavelength range of electromagnetic waves that are emitted changes. As a result, it is thought that, for example, the emission of the electromagnetic waves in the wavelength range in which the resin contained in the heat radiation material does not absorb the electromagnetic waves relatively increases, heat accumulation by the resin is reduced, and heat radiation performance is improved.

The metal particle layer may be located on a surface of the heat radiation material or may be located inside the heat radiation material. Hereinafter, the configuration in which the metal particle layer is located on the surface of the heat radiation material will be described as a “configuration A,” and the case where the metal particle layer is located inside the heat radiation material will be described as a “configuration B.”

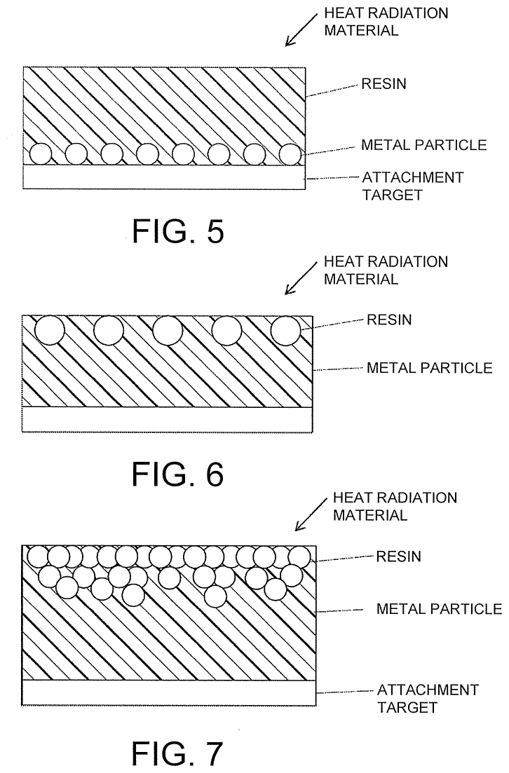

Specific examples of the configuration A of the heat radiation material are shown in FIGS. 5 to 7.

In the heat radiation material shown in FIG. 5, the metal particles arranged in the surface direction form the metal particle layer at a position closer to the attachment target (the heat generator) side.

In the heat radiation material shown in FIG. 6, the metal particles arranged in the surface direction form the metal particle layer at a position closer to a side opposite to the attachment target (the heat generator).

In the heat radiation material shown in FIG. 7, the metal particles arranged in the surface direction form the metal particle layer at a position closer to a side opposite to the attachment target (the heat generator). Further, the metal particle layer contains particles overlapping each other in the thickness direction.

The heat radiation material of a configuration example A may include a region 1 and a region 2 satisfying the following (A) and (B).

(A) a total value of absorption of electromagnetic waves at a wavelength of 2 μm to 6 μm in a region 1>a total value of absorption of electromagnetic waves at a wavelength of 2 μm to 6 μm in a region 2

(B) a metal particle occupancy rate in the region 1>a metal particle occupancy rate in the region 2

The heat radiation material having the above configuration exhibits an excellent heat radiation effect when it is attached to the heat generator. The reasons for this are not necessarily clear, but they are thought to be as follows.

A resin generally has the property of being unlikely to absorb short-wavelength infrared light and easily absorbing long-wavelength infrared light. Therefore, it is thought that, by increasing the absorption of the electromagnetic waves in the wavelength range of 2 μm to 6 μm which the resin is unlikely to absorb (that is, increasing the emission), heat accumulation by the resin is reduced, and heat radiation performance is improved.

The heat radiation material having the above configuration includes the region 1 in which the total value of the absorption of the electromagnetic waves in the wavelength range of 2 μm to 6 μm is higher than that of the region 2, and thus the above-mentioned problems are solved.

Specifically, as the region 1, a metal particle layer that has a fine uneven structure formed by the metal particles by including a relatively large amount of the metal particles and is configured to cause a surface plasmon resonance effect is exemplified. Specifically, as the region 2, a resin layer containing a relatively large amount of the resin is exemplified. One of the region 1 and the region 2 may be disposed on a side of the heat radiation material facing the heat generator, and the other may be disposed on a side opposite to the side of the heat radiation material facing the heat generator.

In the above configuration, the “metal particle occupancy” means the volume-based proportion of the metal particles in the region. The “absorption of the electromagnetic waves” can be measured in the same manner as in the absorption of the electromagnetic waves of the heat radiation material described above.

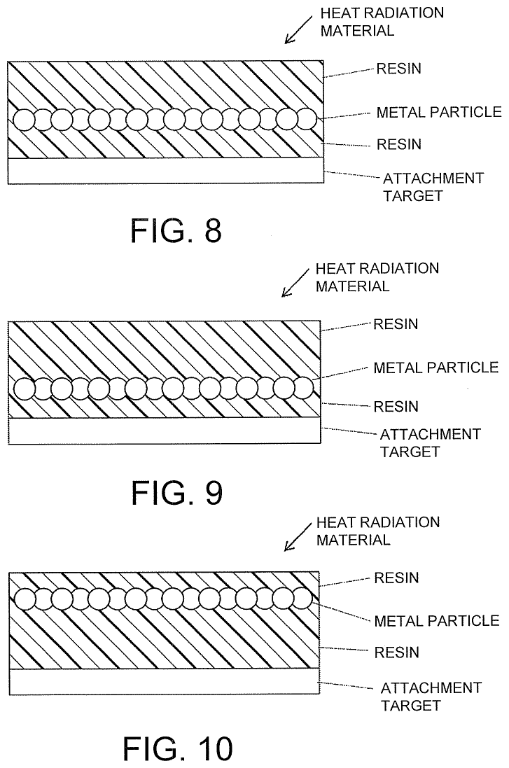

Specific examples of Configuration B of the heat radiation material are shown in FIGS. 8 to 10.

In the heat radiation material shown in FIG. 8, the metal particles arranged in the surface direction form the metal particle layer near the center in the thickness direction.

In the heat radiation material shown in FIG. 9, the metal particles arranged in the surface direction form the metal particle layer at a position closer to the attachment target (the heat generator) side from the center in the thickness direction.

In the heat radiation material shown in FIG. 10, the metal particles arranged in the surface direction form the metal particle layer at a position closer to a side opposite to the attachment target (the heat generator) from the center in the thickness direction.

The heat radiation material of a configuration example B may include a region 1, a region 2, and a region 3 satisfying the following (A) and (B) in that order.

(A) a total value of absorption of electromagnetic waves at a wavelength of 2 μm to 6 μm in the region 2>a total value of absorption of electromagnetic waves at a wavelength of 2 μm to 6 μm in the region 1 and the region 3

(B) a metal particle occupancy rate in the region 2>metal particle occupancy rates in the region 1 and the region 3

The heat radiation material having the above configuration exhibits an excellent heat radiation effect when it is attached to the heat generator. The reasons for this are not necessarily clear, but they are thought to be as follows.

A resin generally has the property of being unlikely to absorb short-wavelength infrared light and easily absorbing long-wavelength infrared light. Therefore, it is thought that, by increasing the absorption of the electromagnetic waves in the wavelength range of 2 μm to 6 μm which the resin is unlikely to absorb (that is, increasing the emission), heat accumulation by the resin is reduced, and heat radiation performance is improved.

The heat radiation material having the above configuration includes the region 2 in which the total value of the absorption of the electromagnetic waves in the wavelength range of 2 μm to 6 μm is higher than that of each of the region 1 and the region 3, and thus the above-mentioned problems are solved.

Specifically, as the region 2, a layer (a metal particle layer) that has a fine uneven structure formed by the metal particles by containing a relatively large amount of the metal particles and is configured to cause a surface plasmon resonance effect is exemplified.

Specifically, as the region 1 and the region 3, a layer (a resin layer) containing a relatively large amount of the resin is exemplified.

The position of the region 2 is not particularly limited as long as it is between the region 1 and the region 3, and the region 2 may be disposed in the center of the heat radiation material in the thickness direction, may be disposed on a side closer to the heat generator, or may be disposed closer to a side opposite to a side facing the heat generator.

A clear boundary may be present or may not be present between adjacent regions (for example, the metal particle occupancy varies stepwise in the thickness direction).

In the above configuration, the “metal particle occupancy” means the volume-based proportion of the metal particles in the region. The “absorption of the electromagnetic waves” can be measured in the same manner as in the absorption of the electromagnetic waves of the heat radiation material described above.

Since the region 2 is disposed between the region 1 and the region 3, the state in which the metal particles contained in the region 2 are arranged is maintained, and there is a trend that stable heat radiation performance is obtained.

The materials contained in the region 1 and the region 3, the thicknesses thereof, and the like may be the same or different. For example, when the region 1 is located on the heat generator side, heat can be transferred more efficiently using a material having high thermal conductivity for the region 1, and a further improvement in heat radiation performance can be expected.

As a method of manufacturing the heat radiation material of the configuration A, a method including a step of forming a layer (a composition layer) of a composition containing metal particles and a resin and a step of arranging the metal particles in the layer is exemplified.

In the above method, the method of executing a step of forming a layer (a composition layer) of a composition containing metal particles and a resin is not particularly limited. For example, the heat radiation material may be manufactured such that the composition has a desired thickness on a base material.

<Case of Varnish Shape>

The base material to which the composition is applied may be removed or may not be removed after the heat radiation material is manufactured or before the heat radiation material is used. As the latter case, a case in which the composition is applied directly to the object (the heat generator) to which the heat radiation material is attached is exemplified. The method of applying the composition is not particularly limited, and known methods such as brush application, spray coating, application by a roll coater, and dip coating may be employed. Electrostatic coating, curtain coating, electrodeposition coating, powder coating, or the like may be employed depending on the object to be applied.

In the above method, a method of executing a step of settling the metal particles in the composition layer is not particularly limited. For example, the metal particles in the composition layer formed on the base material disposed such that the principal surface is horizontal may be left until they naturally settle. From the viewpoint of promoting the settling of metal particles in the composition layer, it is preferable that, when the density (mass per unit volume) of the metal particles is A and the density of components other than the metal particles is B, a relationship of A>B is satisfied.

If necessary, after the step of settling the metal particles in the composition layer in the above method, treatments such as drying, baking, and curing of the resin may be performed.

The types of the metal particles and the resin contained in the composition are not particularly limited. For example, it may be selected from the metal particles and the resin contained in the heat radiation material described above. Further, the composition may contain other materials that may be contained in the heat radiation material described above.

If necessary, the composition may be in a state of a dispersion containing a solvent (aqueous emulsion and the like), varnish, or the like. Examples of the solvent contained in the composition include water and an organic solvent, and it is preferable to select the solvent in consideration of combination with other materials such as metal particles and resin contained in the composition. Examples of the organic solvent include organic solvents such as a ketone solvent, an alcohol solvent, and an aromatic solvent. More specifically, examples of the organic solvent include methyl ethyl ketone, cyclohexene, ethylene glycol, propylene glycol, methyl alcohol, isopropyl alcohol, butanol, benzene, toluene, xylene, ethyl acetate, butyl acetate, and the like. Only one type of solvent may be used, or two or more types of solvents may be used in combination.

The details and the preferred aspect of the heat radiation material manufactured by the above method may be the same as the details and the preferred aspect of the heat radiation material described above, for example.

<Case of Sheet Shape>

The base material to which the composition is attached may be removed or may not be removed after the heat radiation material is manufactured or before the heat radiation material is used. As the latter case, a case in which the composition is applied directly to the object (the heat generator) to which the heat radiation material is attached is exemplified. The method of performing attachment of the composition is not particularly limited, and a known method such as roll attachment may be employed.

The types of the metal particles and the resin contained in the composition are not particularly limited. For example, it may be selected from the metal particles and the resin contained in the heat radiation material described above. Further, the composition may contain other materials that may be contained in the heat radiation material described above.

The details and the preferred aspect of the heat radiation material manufactured by the above method may be the same as the details and the preferred aspect of the heat radiation material described above, for example.

As a method of manufacturing the heat radiation material of the configuration B, a method including a step of disposing the metal particles on a first resin layer and a step of disposing a second resin layer on the metal particles in that order is exemplified.

The first resin layer and the second resin layer used in the above method may contain the resin contained in the above-mentioned heat radiation material and may further contain the ceramic particles, the additives, and the like contained in the above-mentioned heat radiation material. The metal particles used in the above method may be the metal particles contained in the above-mentioned heat radiation material.

The materials and the dimensions of the first resin layer and the second resin layer may be the same or different. From the viewpoint of workability, each resin layer is preferably in a preformed state (a resin film and the like). From the viewpoint of ensuring adhesion between the resin layers and adhesion between each resin layer and the metal particles or the attachment target, both or one of the first resin layer and the second resin layer may have adhesiveness on both surfaces or one surface thereof.

From the viewpoint of suppressing distribution unevenness of the metal particles, it is preferable that a surface of the first resin layer on which the metal particles are disposed has adhesiveness. When the surface of the first resin layer on which the metal particles are disposed has adhesiveness, the movement of the metal particles when the metal particles are disposed on the first resin layer is appropriately controlled, and there is a trend that the distribution unevenness of the metal particles is suppressed.

The method of disposing the metal particles on the first resin layer is not particularly limited. For example, a method of disposing the metal particles or the composition containing the metal particles using a brush, a sieve, an electrospray, a coater, an inkjet device, a screen printing device, or the like is exemplified. When the metal particles form an agglomerate, it is preferable to perform a treatment for crushing the agglomerate before disposition.

The method of disposing the second resin layer on the metal particles disposed on the first resin layer is not particularly limited. For example, a method of laminating the second resin layer having a film shape while heating the second resin layer as needed is exemplified.

### Device (Second Embodiment)

A device of the present disclosure includes a heat generator; a resinous housing covering the heat generator; and a heat radiation material disposed on at least some of a surface of the heat generator, wherein the heat radiation material has a base material layer that contains a resin and has an uneven structure on at least one surface thereof and a metal layer that is disposed on the surface side of the base material layer having the uneven structure and has a shape corresponding to the uneven structure.

In the above device, heat generated from the heat generator is unlikely to accumulate inside the resinous housing, and increase in temperature thereof can be suppressed.

At least some of the heat generator inside the resinous housing is provided with a heat radiation material on a surface thereof. As a result, temperature rise inside the resinous housing is suppressed and an excellent heat radiation effect is achieved. The reasons for this are not necessarily clear, but they are thought to be as follows.

In the heat radiation material, the metal layer is disposed on the surface side of the base material layer having the uneven structure. Therefore, the metal layer has a shape corresponding to the uneven structure of the base material layer.

When the heat radiated from the heat generator is transferred to the metal layer having the uneven structure, the surface plasmon resonance occurs. At this time, if the surface temperature of the heat radiation material is higher than the ambient temperature, electromagnetic waves are emitted from the surface of the heat radiation material to the surroundings. In addition, the emission energy increases as the surface temperature of the heat radiation material rises. Since the wavelength at which the surface plasmon resonance is maximized is controlled, the wavelength range of the electromagnetic waves that are emitted changes.

The wavelength range of the electromagnetic waves to be converted changes depending on the state of an uneven pattern (a shape of the uneven structure) of the heat radiation material. Therefore, it is possible to control the wavelength range of the electromagnetic waves to be converted by changing the shape, the size, the height difference, the interval, and the like of the uneven pattern. As a result, it is thought that, for example, even if a resin member is disposed around the heat generator, the emission of the electromagnetic waves in the wavelength range which are easy to be transmitted by the resin member can be relatively increased, heat accumulation by the resin member is reduced, and the heat radiation performance is improved.

The uneven pattern of the heat radiation material is not particularly limited as long as it can cause the surface plasmon resonance. For example, it is preferable to have a pattern in which concave portions or convex portions having the same shape and size are disposed at equal intervals.

As the shape of the concave portion or the convex portion constituting the uneven pattern of the heat radiation material, a circular shape or a polygonal shape is exemplified.

The shape of the concave portion or the convex portion constituting the uneven pattern may be a shape in which diameters or one side lengths are the same with respect to two axial directions which are orthogonal to each other (for example, a perfect circle or a square), or may be a shape in which diameters or one side lengths are different with respect to two axial directions which are orthogonal to each other (for example, an ellipse or a rectangle).

When the diameters or the one side lengths of the uneven pattern are the same with respect to the two axial directions which are orthogonal to each other, there is a trend that polarization dependence is unlikely to occur, and an absorption spectrum having a single peak wavelength occurs.

When the diameters or the one side lengths of the uneven pattern are different with respect to the two axial directions which are orthogonal to each other, there is a trend that polarization dependence easily occurs, and an absorption spectrum having a plurality of peak wavelengths occurs.

The size of the concave portion or the convex portion constituting the uneven pattern is not particularly limited as long as it is a value at which the surface plasmon resonance can occur at a predetermined wavelength. For example, when the concave portion or the convex portion is circular, the diameter thereof may be in the range of 0.5 μm to 10 μm, and when the concave portion or the convex portion is quadrangular, the one side length thereof may be in the range of 0.5 μm to 10 μm.

The height or depth of the concave portion or the convex portion constituting the uneven pattern is not particularly limited as long as it is a value at which the surface plasmon resonance can occur at a predetermined wavelength. For example, it may be in the range of 0.5 μm to 10 μm.

The aspect ratio (height or depth/size) of the concave portion or the convex portion constituting the uneven pattern is not particularly limited as long as it is a value at which the surface plasmon resonance can occur at a predetermined wavelength. For example, it may be in the range of 0.5 to 2.

The interval of the uneven patterns is not particularly limited as long as it is a value at which the surface plasmon resonance can occur at a predetermined wavelength. For example, it may be in the range of 1 μm to 20 μm. In the present disclosure, the interval of the uneven patterns means the total value of the sizes of a set of the concave portion and the convex portion constituting the uneven pattern.

A specific example of the uneven pattern of the heat radiation material will be described with reference to the drawings.

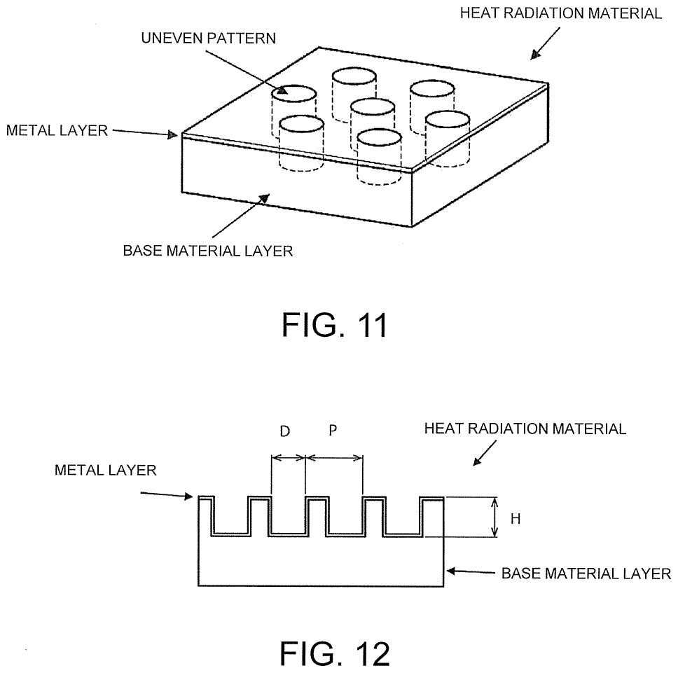

The heat radiation material shown in FIG. 11 is an example that includes the base material layer and the metal layer disposed on one surface side of the base material layer and in which uneven patterns constituted by circular concave portions are formed on a surface on a side on which the metal layer is disposed.

FIG. 12 is a cross-sectional view of the heat radiation material shown in FIG. 11. By changing the values of the diameter D, the depth H, and the interval P of the circular concave portion constituting the uneven pattern, it is possible to control the wavelength range of the electromagnetic waves to be converted within a predetermined range.

(Base Material Layer)

In the heat radiation material of the present disclosure, the base material layer contains a resin. Therefore, it is more likely deformed according to a shape of a surface of an attachment target, and it is possible to achieve superior adhesion to a metallic heat radiation material.

The type of the resin contained in the base material layer is not particularly limited and may be selected from the resins contained in the heat radiation material used in the device of the first embodiment.

The base material layer may contain a material other than the resin. For example, it may contain inorganic particles, additives, and the like. These types are not particularly limited and may be selected from the materials contained in the heat radiation material used in the device of the first embodiment.

The thickness of the base material layer is not particularly limited. From the viewpoint of reducing heat accumulation in the base material layer and ensuring sufficient adhesion to the attachment target, the thickness of the base material layer is preferably 2 mm or less, and more preferably 1 mm or less. On the other hand, from the viewpoint of ensuring sufficient strength, the thickness of the base material layer is preferably 0.1 mm or more, and more preferably 0.5 mm or more. In the present disclosure, the thickness of the base material layer is a value including the height of the convex portion constituting the uneven structure of the base material layer.

(Metal Layer)

Specifically, examples of the metal contained in the metal layer include copper, aluminum, nickel, iron, silver, gold, tin, titanium, chromium, palladium, and the like. The metal contained in the metal layer may be of only one type or may be of two or more types. Further, the metal contained in the metal layer may be a simple substance or may be an alloyed state.

The metal layer having a shape corresponding to the uneven structure of the base material layer can be obtained by, for example, a thin film forming technique such as a known plating method, sputtering method, or vapor deposition method.

The thickness of the metal layer is not particularly limited. From the viewpoint of obtaining sufficient surface plasmon resonance, it is preferably 0.01 μm or more, more preferably 0.05 μm or more, and further preferably 0.1 μm or more. On the other hand, from the viewpoint of ensuring the adhesion of the heat radiation material to the attachment target, it is preferably 10 μm or less, more preferably 5 μm or less, and further preferably 1 μm or less.

Examples of a method of manufacturing the heat radiation material include the following method 1 and method 2.

A method 1 is a method of manufacturing a heat radiation material that includes a step of pressing a mold having an uneven structure against one surface of a resin sheet, a step of removing the mold from the resin sheet, and a step of forming a metal layer on the surface of the resin sheet from which the mold has been removed.

A method 2 is a method of manufacturing the heat radiation material which includes a step of pressing a mold having an uneven structure against one surface of a resin composition layer, a step of curing or solidifying the resin composition layer to obtain a resin sheet, a step of removing the mold from the resin sheet, and a step of forming a metal layer on the surface of the resin sheet from which the mold has been removed.

According to the above methods, it is possible to obtain a heat radiation material by a simple method as compared with, for example, the case of manufacturing the heat radiation material by forming the uneven pattern on the surface of the metal member.

In the above methods, the resin contained in the resin sheet and the resin composition may be the same as the resin contained in the base material layer of the heat radiation material described above, and the details and the preferred aspect thereof are also the same as the resin contained in the base material layer of the heat radiation material described above. The resin sheet and the resin composition may contain the above-mentioned inorganic particles, additives, and the like, as needed.

The metal layer formed by the above methods may be the same as the metal layer included in the heat radiation material described above, and the details and the preferred aspect thereof are also the same as the metal layer provided in the heat radiation material described above.

The details and the preferred configuration of the heat generator and the resinous housing included in the device of the second embodiment are the same as those of the device of the first embodiment.

### Device (Third Embodiment)

A device of the present embodiment is a device that includes a heat generator; a resinous housing covering the heat generator; and a heat radiation material disposed on at least some of a surface of the heat generator, wherein the heat radiation material has a resin layer and a metal pattern layer including a region A in which a metal is present and a region B in which a metal is not present.

In the above device, heat generated from the heat generator is unlikely to accumulate inside the resinous housing, and increase in temperature thereof can be suppressed.

At least some of the heat generator inside the resinous housing is provided with a heat radiation material on a surface thereof. As a result, temperature rise inside the resinous housing is suppressed and an excellent heat radiation effect is achieved. The reasons for this are not necessarily clear, but they are thought to be as follows.

In the heat radiation material, the metal pattern layer is constituted by the region A in which a metal is present (hereinafter also simply referred to as a region A) and the region B in which a metal is not present (hereinafter also simply referred to as a region B). When the heat radiated from the heat generator is transferred to the metal pattern layer, the surface plasmon resonance occurs. At this time, if the surface temperature of the heat radiation material is higher than the ambient temperature, electromagnetic waves are emitted from the surface of the heat radiation material to the surroundings. In addition, the emission energy increases as the surface temperature of the heat radiation material rises. Since the wavelength at which the surface plasmon resonance is maximized is controlled, the wavelength range of the electromagnetic waves that are emitted changes.

The wavelength range of the electromagnetic waves to be converted changes depending on the state of the metal pattern layer of the heat radiation material. Therefore, it is possible to control the wavelength range of the electromagnetic waves to be converted by changing the shapes, the sizes, the thickness, the interval, and the like of the region A and the region B constituting the metal pattern layer. As a result, it is thought that, for example, even if a resin member is disposed around the heat generator, the emission of the electromagnetic waves in the wavelength range which are easy to be transmitted by the resin member can be relatively increased, heat accumulation by the resin member is reduced, and the heat radiation performance is improved.

A metal pattern constituted by the region A and the region B is not particularly limited as long as it can cause the surface plasmon resonance. For example, it is preferable to have a pattern in which the region A or the region B having the same shape and size are disposed at equal intervals.

As the shape of the region A or the region B, a circle or a polygon is exemplified. In this case, either the shape of the region A or the region B may be circular or polygonal, or both shapes may be circular or polygonal.

The shape of the region A or the region B may be a shape in which diameters or one side lengths are the same with respect to two axial directions which are orthogonal to each other (for example, a perfect circle or a square), or may be a shape in which diameters or one side lengths are different with respect to two axial directions which are orthogonal to each other (for example, an ellipse or a rectangle).

When the diameters or the one side lengths of the region A or the region B are the same with respect to the two axial directions which are orthogonal to each other, there is a trend that polarization dependence is unlikely to occur, and an absorption spectrum having a single peak wavelength occurs.

When the diameters or the one side lengths of the region A or the region B are different with respect to the two axial directions which are orthogonal to each other, there is a trend that polarization dependence easily occurs, and an absorption spectrum having a plurality of peak wavelengths occurs.

The size of the region A or the region B is not particularly limited as long as it is a value at which the surface plasmon resonance can occur at a predetermined wavelength. For example, when the region A or the region B is circular, the diameter thereof may be in the range of 0.5 μm to 10 μm, and when the region A or the region B is quadrangular, the one side length thereof may be in the range of 0.5 μm to 10 μm.

The interval of the metal patterns constituted by the region A and the region B is not particularly limited as long as it is a value at which the surface plasmon resonance can occur at a predetermined wavelength. For example, it may be in the range of 1 μm to 20 μm. In the present disclosure, the interval of the metal patterns means the total value of the sizes of a set of the region A or the region B constituting the metal pattern.

The thickness of the region A or the region B is not particularly limited as long as it is a value at which the surface plasmon resonance can occur at a predetermined wavelength. For example, it may be in the range of 0.01 μm to 10 μm.

The aspect ratio (thickness/size) of the region A or the region B is not particularly limited as long as it is a value at which the surface plasmon resonance can occur at a predetermined wavelength. For example, it may be in the range of 0.01 to 2.

The metal pattern layer may be disposed outside the resin layer or may be disposed inside the resin layer. When the metal pattern layer is disposed inside the resin layer, the metal pattern layer may be disposed between the two resin layers. In this case, the materials of the two resin layers may be the same or different.

In the following, when the metal pattern layer is disposed between the two resin layers, the resin layer on the attachment target side may be referred to as “Resin layer 1”, and the resin layer on a side opposite to the attachment target may be referred to as “Resin layer 2.”

A specific example of the heat radiation material of the present disclosure will be described with reference to the drawings.

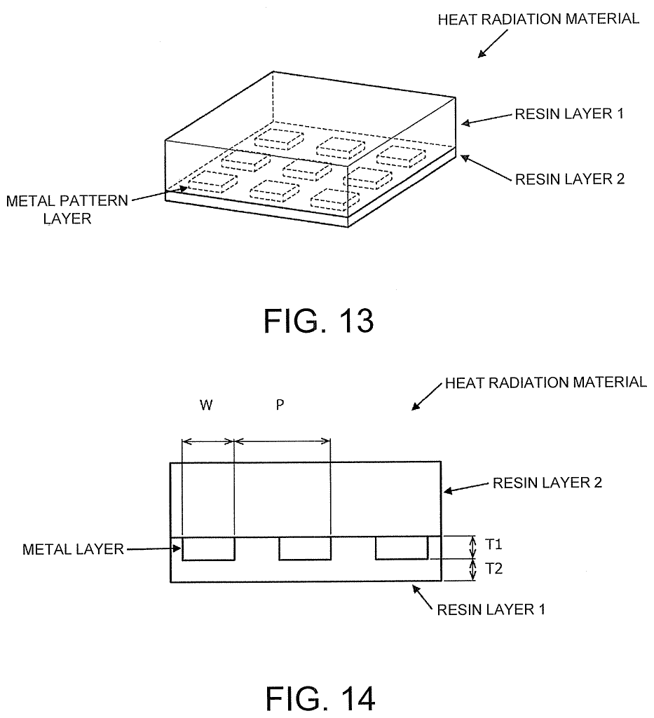

The heat radiation material shown in FIG. 13 is an example that includes a resin layer 1, a resin layer 2, and a metal pattern layer disposed between them, and the metal pattern layer is constituted by a square region A and a surrounding region B thereof.

FIG. 14 is a cross-sectional view of the heat radiation material shown in FIG. 13. By changing the values of the one side length W, the thickness T, and the interval P of the region A constituting the metal pattern, it is possible to control the wavelength range of the electromagnetic waves to be converted within a predetermined range.

(Resin Layer)

The heat radiation material of the present disclosure has the resin layer. Therefore, it is more likely deformed according to a shape of a surface of an attachment target, and it is possible to achieve superior adhesion to a metallic heat radiation material.

The type of the resin contained in the base material layer is not particularly limited and may be selected from the resins contained in the heat radiation material used in the device of the first embodiment.

The resin layer may contain a material other than the resin. For example, it may contain inorganic particles, additives, and the like. These types are not particularly limited and may be selected from the materials contained in the heat radiation material used in the device of the first embodiment.

When the heat radiation material has two or more resin layers, the materials of the two resin layers (the types of the resins contained in the resin layer and the like) may be the same or different. Further, the resin layer may have a function as a protective layer for protecting the metal pattern layer, an adhesion layer for fixing the heat radiation material to the attachment target, and the like.

The thickness of the resin layer is not particularly limited. From the viewpoint of suppressing heat accumulation in the resin layer and ensuring sufficient adhesion to the attachment target, the thickness of the resin layer is preferably 2 mm or less, and more preferably 1 mm or less. On the other hand, from the viewpoint of ensuring sufficient strength, the thickness of the resin layer is preferably 0.1 mm or more, and more preferably 0.5 mm or more. When the heat radiation material contains two or more resin layers, the thickness is the total thickness of the two or more resin layers.

Some of the resin layer may form the region B of the metal pattern layer. In this case, the thickness of the resin layer is the thickness of a portion excluding the thickness of the region B of the metal pattern layer. For example, when the resin layer is constituted by the resin layer 1 and the resin layer 2, the thickness of the resin layer 1 is the thickness corresponding to T2 in the drawing.

From the viewpoint of a heat radiation effect, it is preferable that the thickness of a portion of the resin layer located on the attachment target side rather than the metal pattern layer is smaller. For example, it is preferably 0.5 μm or less, more preferably 0.2 μm or less, and further preferably 0.1 μm or less.

(Metal Pattern Layer)

Specifically, examples of the metal contained in the metal pattern layer include copper, aluminum, nickel, iron, silver, gold, tin, titanium, chromium, palladium, and the like. The metal contained in the metal layer may be of only one type or may be of two or more types. Further, the metal contained in the metal pattern layer may be a simple substance or may be an alloyed state.

It is possible to form the metal pattern layer having a pattern constituted by the region A in which the metal is present and the region B in which the metal is not present by forming a metal thin film on the resin layer by, for example, a thin film forming technique such as a known plating method, sputtering method, or vapor deposition method, forming a mask pattern by a lithography method or the like, and removing a portion corresponding to the region B. Alternatively, after forming the mask pattern on the resin layer, the metal thin film can be formed only in a portion corresponding to the region A.

The thickness of the metal pattern layer is not particularly limited. From the viewpoint of obtaining sufficient surface plasmon resonance, it is preferably 0.01 μm or more, more preferably 0.05 μm or more, and further preferably 0.1 μm or more. On the other hand, from the viewpoint of ensuring the adhesion of the heat radiation material to the attachment target, it is preferably 10 μm or less, more preferably 5 μm or less, and further preferably 1 μm or less.

Examples of a method of manufacturing the heat radiation material include the following method 1 and method 2.

A method 1 is a method of manufacturing a heat radiation material which includes a step of forming a metal thin film on one surface of a resin layer, and a step of removing some of the metal thin film to form a metal pattern constituted by a region A in which a metal is present and a region B in which a metal is not present.

A method 2 is a method of manufacturing a heat radiation material that includes a step of forming a mask pattern on one surface of a resin layer, and a step of forming a metal pattern constituted by a region A in which a metal is present and a region B in which a metal is not present via the mask pattern.

If necessary, the above method may further include a step of disposing another resin layer on the metal pattern.

According to the above methods, it is possible to manufacture a heat radiation material by a simple method as compared with, for example, the case of manufacturing the heat radiation material by forming the uneven pattern on the surface of the metal member.

The method for forming the metal thin film and the mask pattern in the above method is not particularly limited, and a known method can be used.

In the above methods, the resin contained in the resin sheet may be the same as the resin contained in the resin layer of the heat radiation material described above, and the details and the preferred aspect thereof are also the same as the resin contained in the resin layer of the heat radiation material described above. The resin sheet may contain the above-mentioned inorganic particles, additives, and the like, as needed.

The metal pattern formed by the above methods may be the same as the metal pattern layer included in the heat radiation material described above, and the details and the preferred aspect thereof are also the same as the metal pattern layer provided in the heat radiation material described above.

The details and the preferred configuration of the heat generator and the resinous housing included in the device of the third embodiment are the same as those of the device of the first embodiment.

<Heat Radiation Method>

A heat radiation method of the present disclosure is a heat radiation method that includes a step of disposing a heat radiation material on at least some of a surface of a heat generator covered with a resinous housing, wherein the heat radiation material contains metal particles and a resin and has a region where the metal particles arranged in a surface direction are present at a relatively high density.

According to the above method, heat generated from the heat generator is unlikely to accumulate inside the resinous housing, and increase in temperature thereof can be suppressed.

The details and the preferred aspects of the resinous housing, the heat generator, and the heat radiation material used in the above method are the same as the details and the preferred aspects of the resinous housing, heat generator, and the heat radiation material used in the device of the present disclosure.

### EXAMPLES

Hereinafter, the present disclosure will be described in more detail with reference to Examples. However, the present disclosure is not limited to the contents described in the following Examples.

### Example 1

99.13% by volume of an acrylic resin, 0.87% by volume of copper particles (volume average particle diameter: 2 μm), and 30% by mass of butyl acetate with respect to 100% by mass of the total of the two components were put in a container and mixed using hybrid mixer to prepare a composition. This composition was spray-coated on an electronic component as a heat generator using a spray coating device to form a composition layer. This composition layer was naturally dried and heat-cured at 60° C. for 30 minutes to manufacture a sample in which a heat radiation material having a film thickness of 100 μm is formed on a surface of the electronic component.

The thermal emission of the prepared sample was measured at room temperature (25° C.) using an emission measuring device (D and S AERD, manufactured by Kyoto Electronics Manufacturing Co., Ltd.) (measurement wavelength range: 3 μm to 30 μm). The emission of the heat radiation material of Example 1 was 0.9.

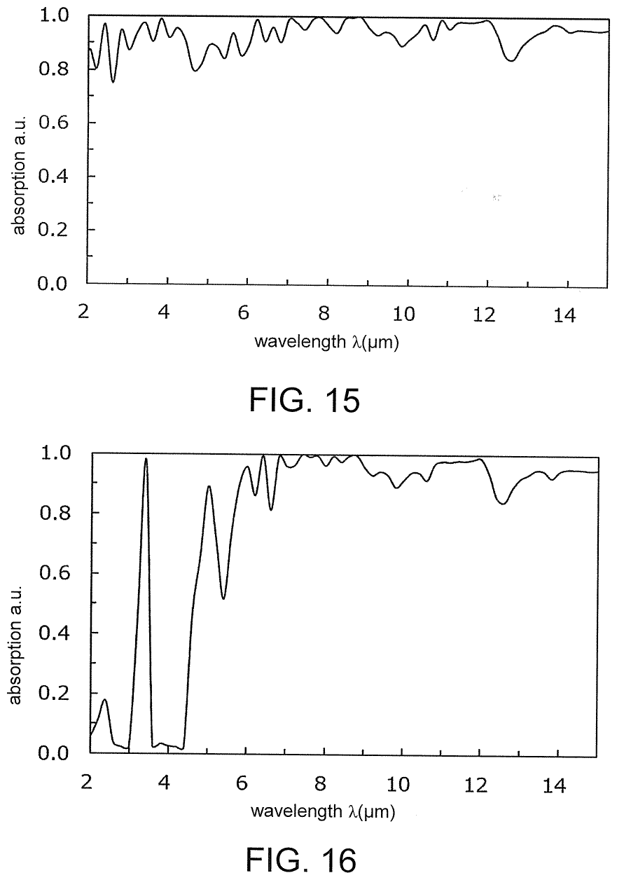

The absorption wavelength spectrum of the manufactured heat radiation material was examined by a Fourier transform infrared spectrophotometer. The obtained absorption wavelength spectrum is shown in FIG. 15.

Further, the absorption wavelength spectrum of a resinous housing used in the test that will be described later was examined by a Fourier transform infrared spectrophotometer. The obtained absorption wavelength spectrum is shown in FIG. 16.

It is possible to confirm that the manufactured heat radiation material has a higher absorption efficiency in a low wavelength range (particularly 2 μm to 6 μm) than the resinous housing.

### Example 2

By placing 5 g of copper particles (volume average particle diameter: 1.6 μm) crushed using a vibration stirrer on one side of an acrylic double-sided tape having no base material (thickness: 25 μm), uniformly spreading the copper particles using a commercially available brush, and removing the excess copper particles with an air duster, a metal particle layer was formed on the acrylic double-sided tape. Next, an acrylic resin film (Tg: 75° C., molecular weight: 30000, thickness: 25 μm) formed on polyethylene terephthalate (a PET base material) was heat-laminated at 80° C., and then the PET base material was peeled off to obtain a heat radiation material. Next, a surface opposite to a side on which the base material was peeled off was attached onto an electronic component to manufacture a sample in which a heat radiation material having a thickness of 50 μm was formed on a surface of the electronic component.

### Comparative Example 1

30% by mass of butyl acetate was mixed with respect to 100% by mass of an acrylic resin to prepare a composition having an adjusted viscosity. This composition was spray-coated on an electronic component using a spray coating device to form a composition layer. This composition layer was naturally dried and heat-cured at 60° C. for 30 minutes to manufacture a sample having a film thickness of 100 μm.

The emission of the sample of Comparative Example 1 measured in the same manner as in Example 1 was 0.7.

### Comparative Example 2

A commercially available heat radiation paint containing 95% by volume of an acrylic resin and 5% by volume of silicon dioxide particles (volume average particle diameter 2: μm) was spray-coated on an electronic component using a spray coating device to form a composition layer. This composition layer was naturally dried and heat-cured at 60° C. for 30 minutes to manufacture a sample having a film thickness of 100 μm (silicon dioxide particles are uniformly dispersed in the resin).

The emission of the sample of Comparative Example 3 measured in the same manner as in Example 1 was 0.81.

<Evaluation of Heat Radiation Performance>

The samples of Examples and Comparative Examples were mounted on a circuit board and were covered with a resinous housing (made of an acrylic resin) to manufacture a device having a configuration as shown in FIG. 1, and heat radiation performance was evaluated by the following method. The results are shown in Table 1.

A type K thermocouple is adhered to a surface of an electronic component (a heat radiation material) in the device and inner and outer surfaces of the resinous housing. The device is allowed to stand in a constant temperature bath set at 25° C., and the surface temperature of the electronic component and the temperatures inside and outside the resinous housing are measured. At this time, the output of the electronic component is set such that the surface temperature of the electronic component in the state where the heat radiation material is not formed becomes 100° C. Since the electronic component generates a certain amount of heat, the higher the heat radiation effect of the electronic component, the lower the temperature of the surface of the electronic component. That is, it can be said that the lower the surface temperature of the electronic component, the higher the heat radiation effect. Further, when the absorption of the electromagnetic waves of the heat radiation material in the wavelength range of 2 μm to 6 μm is higher than that of the resinous housing, the temperatures on inside and outside the resinous housing decrease. That is, it can be said that the lower the temperatures inside and outside the resinous housing, the higher the heat radiation effect. The measured surface temperature (a maximum temperature) is shown in Table 1.

TABLE 1

| Temperature | Comparative | Comparative | | |
|---|---|---|---|---|
| (° C.) | Example 1 | Example 2 | Example 1 | Example 2 |
| Electronic | 90 | 85 | 70 | 70 |
| component | | | | |
| surface | | | | |
| Resinous | 75 | 70 | 55 | 54 |
| housing inside | | | | |
| Resinous | 55 | 45 | 35 | 34 |
| housing outside | | | | |

As shown in Table 1, in Comparative Example 1 to which the sample made of only a resin was attached, the surface temperature of the electronic component was reduced to 90° C., but the reduction effect was smaller than that in Examples. It is thought that this is because the sample does not contain the metal particle layer, and thus the heat radiation effect due to heat radiation heat transfer is smaller than that in Examples.

In Comparative Example 2 to which the sample having a structure in which silicon dioxide particles were uniformly dispersed in the resin was attached, the surface temperature of an aluminum plate was reduced to 85° C., but the reduction effect was smaller than that in Examples. It is thought that this is because the silicon dioxide particles are uniformly dispersed in the resin, and thus a heat radiation performance amplification effect due to surface plasmon resonance is not sufficiently obtained.

As for the inner surface and the outer surface of the resinous housing, the temperature reduction effect of the examples is greater when Comparative Examples and Examples are compared with each other. It is thought that this is because the absorption of the sample (the heat radiation material) of Examples is larger than the absorption of electromagnetic waves of the resinous housing in the wavelength range of 2 μm to 6 μm, and thus infrared radiation in the wavelength range in which the infrared rays are transmitted through the resinous housing are emitted, and the temperatures inside and outside the resinous housing have decreased.

### Example 3

As shown in FIG. 2, the temperature reduction effect of the device in which the heat radiation material manufactured in Example 1 was also formed on the circuit board in addition to the electronic component and which is covered with the resinous housing was examined.

When the heat radiation performance was evaluated, the temperature of the electronic component was lowered to 65° C. Further, the temperature inside the resinous housing was lowered to 50° C., and the temperature outside thereof was lowered to 30° C.

### Example 4

As shown in FIG. 3, the temperature reduction effect of the device in which one surface of the circuit board on which the electronic component on which the heat radiation material manufactured in Example 1 is disposed is mounted is in contact with the resinous housing was examined.

When the heat radiation performance was evaluated, the temperature of the electronic component was lowered to 60° C. Further, the temperature inside the resinous housing was 55° C., and the temperature outside thereof was 53° C.

### Comparative Example 3

The temperature reduction effect of the device was examined in the same manner as in Example 4 except that the heat radiation material was changed to the heat radiation material manufactured in Comparative Example 1.

When the heat radiation performance was evaluated, the temperature of the electronic component was 70° C., the temperature inside the resinous housing was 63° C., and the temperature outside thereof was 60° C.

### Example 5

As shown in FIG. 4, the temperature reduction effect of the device in which the electronic component on which the heat radiation material manufactured in Example 1 is disposed is in contact with the resinous housing directly or via the heat radiation material was examined.

When the heat radiation performance was evaluated, the temperature of the electronic component was lowered to 63° C. Further, the temperature inside the resinous housing was 53° C., and the temperature outside thereof was 51° C.

### Comparative Example 4

The temperature reduction effect of the device was examined in the same manner as in Example 5 except that the heat radiation material was changed to the heat radiation material manufactured in Comparative Example 1.

When the heat radiation performance was evaluated, the temperature of the electronic component was 80° C., the temperature inside the resinous housing was 70° C., and the temperature outside thereof was 51° C.

All of the documents, the patent applications, and the technical standards described herein are incorporated herein to the extent that the incorporation of the individual documents, patent applications, and technical standards by reference is the same as a case in which they are specifically and individually stated.

1. A device comprising:
a heat generator;
a resinous housing covering the heat generator; and
a heat radiation material disposed on at least some of a surface of the heat generator,
wherein the heat radiation material contains metal particles and a resin and has a region in which the metal particles arranged in a surface direction are present at a relatively high density.

2. The device according to claim 1,
wherein the heat generator is an electronic component, and
wherein the device further comprises:
a circuit board on which the electronic component is mounted; and
the heat radiation material disposed on at least some of a surface of the circuit board.

3. The device according to claim 1, wherein a thickness of the heat radiation material is in a range of 0.1 μm to 100 μm.

4. The device according to claim 1, wherein a proportion of a thickness of the region in a total thickness of the heat radiation material is in a range of 0.02% to 99%.

5. The device according to claim 1, wherein the region has an uneven structure derived from the metal particles on a surface thereof.

6. The device according to claim 1, wherein the heat radiation material comprises a region 1 and a region 2, and
the region 1 and the region 2 are satisfying the following (A) and (B):
(A) a total value of absorption of electromagnetic waves at a wavelength of 2 μm to 6 μm in the region 1>a total value of absorption of electromagnetic waves at a wavelength of 2 μm to 6 μm in the region 2, and
(B) a metal particle occupancy rate in the region 1>a metal particle occupancy rate in the region 2.

7. The device according to claim 1, wherein the heat radiation material comprises a region 1, a region 2, and a region 3, and
the region 1, the region 2, and the region 3 are satisfying the following (A) and (B):
(A) a total value of absorption of electromagnetic waves at a wavelength of 2 μm to 6 μm in the region 2>a total value of absorption of electromagnetic waves at a wavelength of 2 μm to 6 μm in the region 1 and the region 3, and
(B) a metal particle occupancy rate in the region 2>metal particle occupancy rates in the region 1 and the region 3.

8. The device according to claim 1, wherein a total value of absorption of electromagnetic waves at a wavelength of 2 μm to 6 μm in the heat radiation material is larger than a total value of absorption of electromagnetic waves at a wavelength of 2 μm to 6 μm in the resinous housing.

9. A device comprising:
a heat generator;
a resinous housing covering the heat generator; and
a heat radiation material disposed on at least some of a surface of the heat generator,
wherein the heat radiation material has a base material layer that contains a resin and has an uneven structure on at least one surface thereof and a metal layer that is disposed on the surface side of the base material layer having the uneven structure and has a shape corresponding to the uneven structure.

10. A device comprising:
a heat generator;
a resinous housing covering the heat generator; and
a heat radiation material disposed on at least some of a surface of the heat generator,
wherein the heat radiation material has a resin layer and a metal pattern layer comprising a region A in which a metal is present and a region B in which a metal is not present.

11. A heat radiation method comprising:
a step of disposing a heat radiation material on at least some of a surface of a heat generator covered with a resinous housing,
wherein the heat radiation material contains metal particles and a resin and has a region where the metal particles arranged in a surface direction are present at a relatively high density.

12. The device according to claim 2, wherein a thickness of the heat radiation material is in a range of 0.1 μm to 100 μm.

13. The device according to claim 2, wherein a proportion of a thickness of the region in a total thickness of the heat radiation material is in a range of 0.02% to 99%.

14. The device according to claim 3, wherein a proportion of a thickness of the region in a total thickness of the heat radiation material is in a range of 0.02% to 99%.

15. The device according to claim 2, wherein the region has an uneven structure derived from the metal particles on a surface thereof.

16. The device according to claim 3, wherein the region has an uneven structure derived from the metal particles on a surface thereof.

17. The device according to claim 4, wherein the region has an uneven structure derived from the metal particles on a surface thereof.

18. The device according to claim 2, wherein the heat radiation material comprises a region 1 and a region 2, and
the region 1 and the region 2 are satisfying the following (A) and (B):
(A) a total value of absorption of electromagnetic waves at a wavelength of 2 μm to 6 μm in the region 1>a total value of absorption of electromagnetic waves at a wavelength of 2 μm to 6 μm in the region 2, and
(B) a metal particle occupancy rate in the region 1>a metal particle occupancy rate in the region 2.

19. The device according to claim 3, wherein the heat radiation material comprises a region 1 and a region 2, and
the region 1 and the region 2 are satisfying the following (A) and (B):
(A) a total value of absorption of electromagnetic waves at a wavelength of 2 μm to 6 μm in the region 1>a total value of absorption of electromagnetic waves at a wavelength of 2 μm to 6 μm in the region 2, and
(B) a metal particle occupancy rate in the region 1>a metal particle occupancy rate in the region 2.

20. The device according to claim 4, wherein the heat radiation material comprises a region 1 and a region 2, and
the region 1 and the region 2 are satisfying the following (A) and (B):
(A) a total value of absorption of electromagnetic waves at a wavelength of 2 μm to 6 μm in the region 1>a total value of absorption of electromagnetic waves at a wavelength of 2 μm to 6 μm in the region 2, and
(B) a metal particle occupancy rate in the region 1>a metal particle occupancy rate in the region 2.
